(19) United States
(12) Patent Application Publication
(10) Pub. No.: US 2025/0351704 A1
(43) Pub. Date: Nov. 13, 2025

(54) DISPLAY DEVICE AND METHOD OF FABRICATING THE SAME

(71) Applicant: Samsung Display Co., LTD., Yongin-si (KR)

(72) Inventor: Hyun Eok SHIN, Yongin-si (KR)

(21) Appl. No.: 19/004,397

(22) Filed: Dec. 29, 2024

(30) Foreign Application Priority Data
May 13, 2024 (KR) 10-2024-0062357

(51) Int. Cl. H10K 59/80; H10H 29/01; H10H 29/37; H10H 29/80; H10K 59/12; H10K 59/122; H10K 59/35; H10K 102/00; H10K 102/10

(52) U.S. Cl. CPC H10K 59/80522; H10H 29/032; H10H 29/37; H10H 29/8323; H10K 59/1201; H10K 59/122; H10K 59/35; H10K 2102/101; H10K 2102/351

(57) ABSTRACT

A display device includes a substrate including a light emission area and a non-light emission area; an anode electrode positioned on the light emission area of the substrate; a light emitting layer positioned on the anode electrode; a cathode electrode positioned on the light emitting layer; a protective electrode positioned on the cathode electrode; a pixel defining layer positioned on the non-light emission area of the substrate, defining an opening; and a common electrode positioned on the pixel defining layer and in contact with the protective electrode at a portion that overlaps the opening. An inclination angle of a side surface of the light emitting layer, which faces the non-light emission area, with respect to an upper surface of the anode electrode is 60° to 90°.

This application claims priority to Korean Patent Application No. 10-2024-0062357 filed on May 13, 2024, and all the benefits accruing therefrom under 35 U.S.C. § 119, the content of which in its entirety is herein incorporated by reference.

### BACKGROUND

### Technical Field

The present disclosure relates to a display device and a method of fabricating the same.

### Description of the Related Art

With the advancement of the information age, the demand for a display device for displaying an image has increased with various forms. For example, the display device has been applied to various electronic devices such as a smart phone, a digital camera, a laptop computer, a navigator and a smart television. The display device may be a flat panel display device such as a liquid crystal display device, a field emission display device and an organic light emitting display device. Among the flat panel display devices, the light emitting display device includes a light emitting element in which each of pixels of a display panel may self-emit light, thereby displaying an image even without a backlight unit that provides the display panel with light.

With the development of various electronic devices, there is an increasing demand for a display device of high resolution. In case of the display device of high resolution, since high pixel integration is required, an interval between light emitting elements, which overlap each light emission area, may be narrowed. Therefore, the display device of high resolution may be formed by a pattern process of forming individual pixels, rather than a mask process.

### SUMMARY

An aspect of the present disclosure is to provide a display device of high resolution and a method of fabricating the same, in which a damage defect of a light emitting layer and a cathode electrode, which is caused in a fabricating process of the display device of high resolution, is resolved.

The aspects of the present disclosure are not limited to those mentioned above and additional aspects of the present disclosure, which are not mentioned herein, will be clearly understood by those skilled in the art from the following description of the present disclosure.

Details of the other embodiments are included in the detailed description and drawings.

In an embodiment of the disclosure, a display device includes a substrate including a light emission area and a non-light emission area; an anode electrode positioned on the light emission area of the substrate; a light emitting layer positioned on the anode electrode; a cathode electrode positioned on the light emitting layer; a protective electrode positioned on the cathode electrode; a pixel defining layer positioned on the non-light emission area of the substrate, and defining an opening therein; and a common electrode positioned on the pixel defining layer and in contact with the protective electrode at a portion that overlaps the opening, where a first inclination angle of a side surface of the light emitting layer, which faces the non-light emission area, with respect to an upper surface of the anode electrode is 60° to 90°.

In an embodiment, the cathode electrode may include a side surface facing the non-light emission area, and a second inclination angle of the side surface of the cathode electrode with respect to an upper surface of the light emitting layer may be 60° to 90°.

In an embodiment, the cathode electrode may not cover the side surface of the light emitting layer.

In an embodiment, the cathode electrode may include metal oxide.

In an embodiment, the cathode electrode may include at least one of ytterbium oxide (Yb₂O₃) or terbium oxide (Tb₂O₃).

In an embodiment, a thickness of the cathode electrode in a direction perpendicular to a major surface of the substrate may be 5 angstroms (Å) or more and 15Å or less.

In an embodiment, the side surface of the light emitting layer and the side surface of the cathode electrode may be aligned in the same line.

In an embodiment, the protective electrode may include an oxidation protective electrode positioned on the cathode electrode, and the oxidation protective electrode may include Ag-alloy metal.

In an embodiment, the oxidation protective electrode may include a side surface facing the non-light emission area, and a third inclination angle of the side surface of the oxidation protective electrode with respect to an upper surface of the cathode electrode may be 60° to 90°.

In an embodiment, the oxidation protective electrode may not cover the side surface of the cathode electrode, which may face the non-light emission area.

In an embodiment, a thickness of the oxidation protective electrode in a direction perpendicular to a major surface of the substrate may be 80Å or more and 150Å or less.

In an embodiment, the protective electrode may further include a moisture-permeable protective electrode positioned on the oxidation protective electrode, and the moisture-permeable protective electrode may include a transparent oxide electrode.

In an embodiment, the moisture-permeable protective electrode may include a side surface facing the non-light emission area, and a fourth inclination angle of the side surface of the moisture-permeable protective electrode with respect to an upper surface of the oxidation protective electrode may be 60° to 90°.

In an embodiment, the moisture-permeable protective electrode may not cover the side surface of the oxidation protective electrode, which faces the non-light emission area.

In an embodiment, a thickness of the moisture-permeable protective electrode in a direction perpendicular to a major surface of the substrate may be 70Å or more and 300Å or less.

In an embodiment, the pixel defining layer may be in contact with the side surface of the moisture-permeable protective electrode, the side surface of the oxidation protective electrode, the side surface of the cathode electrode and the side surface of the light emitting layer, and the pixel defining layer completely covers the side surface of the moisture-permeable protective electrode, the side surface of the oxidation protective electrode, the side surface of the cathode electrode and the side surface of the light emitting layer.

In an embodiment of the disclosure, a display device includes a substrate including a light emission area and a non-light emission area; a first anode electrode positioned on the light emission area of the substrate; a first cathode electrode positioned on the first anode electrode; a first protective electrode positioned on the first cathode electrode; a pixel defining layer positioned on the non-light emission area of the substrate; a second anode electrode spaced apart from the first anode electrode with the pixel defining layer interposed therebetween; a second cathode electrode positioned on the second anode electrode; a second protective electrode positioned on the second cathode electrode; and a common electrode positioned on the pixel defining layer and overlapped with the light emission area and the non-light emission area, wherein the common electrode includes a first portion that is in contact with the first protective electrode, a second portion that is in contact with the second protective electrode and a third portion that is in contact with the pixel defining layer, the third portion is positioned between the first portion and the second portion, and the first portion and the second portion are extended from the third portion.

In an embodiment, the first cathode electrode and the second cathode electrode may be spaced apart from each other with the pixel defining layer interposed therebetween, and the first cathode electrode and the second cathode electrode may be electrically connected to each other by the common electrode.

In an embodiment, the first protective electrode may include a first oxidation protective electrode positioned on the first cathode electrode and a first moisture-permeable protective electrode positioned on the first oxidation protective electrode, the second protective electrode includes a second oxidation protective electrode positioned on the second cathode electrode and a second moisture-permeable protective electrode positioned on the second oxidation protective electrode, the first moisture-permeable protective electrode and the second moisture-permeable protective electrode are spaced apart from each other, and the first moisture-permeable protective electrode and the second moisture-permeable protective electrode are electrically connected to each other by the common electrode.

In an embodiment of the disclosure, a method of fabricating a display device, the method includes forming an anode electrode on a substrate, and sequentially stacking and forming a light emitting layer, a cathode electrode and a protective electrode on the anode electrode; forming a photoresist on the protective electrode and then performing an etching process to simultaneously remove a portion of each of the light emitting layer, the cathode electrode and the protective electrode; and forming a pixel defining layer covering an edge of the protective electrode and then forming a common electrode on the pixel defining layer, the common electrode being in contact with the protective electrode and electrically connected to the protective electrode, where an inclination angle of a side surface of the light emitting layer with respect to an upper surface of the anode electrode is 60° to 90°.

According to the display device according to one embodiment, a plurality of light emitting elements may be formed by a photo pattern process, whereby a display device of high resolution may be provided. In addition, the display device according to one embodiment includes a cathode electrode having oxidation resistance properties, so that the light emitting layer and the cathode electrode may be patterned by the same photo pattern process. Also, the display device according to one embodiment includes a passivation electrode on the cathode electrode, so that a damage defect of the light emitting element, which is caused in the fabricating process, may be resolved.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one embodiment;

FIG. 2 is a schematic cross-sectional view illustrating the display device of FIG. 1;

FIG. 3 is a plan view illustrating arrangement of a light emission area in a display area of FIG. 2;

FIG. 4 is a schematic cross-sectional view taken along line X1-X1′ of FIG. 3;

FIG. 5 is a schematic enlarged cross-sectional view illustrating a display element layer that overlaps a first light emission area in FIG. 4;

FIG. 6 is a schematic enlarged cross-sectional view illustrating a display element layer that overlaps a non-light emission area positioned between a first light emission area and a second light emission area in FIG. 4; and

FIGS. 7 to 16 are cross-sectional views illustrating a method of fabricating a display element layer and a thin film encapsulation layer in FIG. 4.

FIG. 17 is a block diagram of an electronic device according to one embodiment of the present disclosure.

FIG. 18 is a schematic diagram of an electronic device according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Throughout the disclosure, the expression “at least one of a, b or c” indicates only a, only b, only c, both a and b, both a and c, both b and c, all of a, b, and c, or variations thereof. Hereinafter, embodiments of the present disclosure will be described in detail with reference to the accompanying drawings.

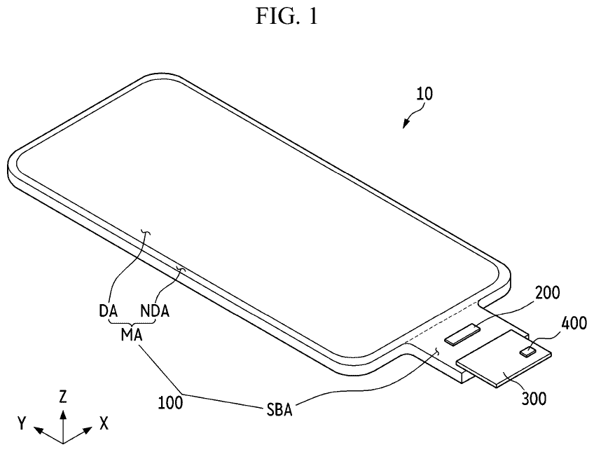

FIG. 1 is a perspective view illustrating a display device according to one embodiment.

Referring to FIG. 1, a display device 10 displays a moving image or a still image. The display device 10 may be referred to as all electronic devices that provide a display screen. For example, a television, a laptop computer, a monitor, an advertising board, Internet of Things, a mobile phone, a smart phone, a tablet personal computer (“PC”), an electronic watch, smart glasses, a smart watch, a watch phone, a head mounted display, a mobile communication terminal, an electronic diary, an electronic book, a portable multimedia player (“PMP”), a navigator, a game machine, a digital camera, a camcorder and the like, which provide a display screen, may be included in the display device 10.

In FIG. 1, a first direction (X-axis direction), a second direction (Y-axis direction) and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a horizontal direction in the drawing, the second direction (Y-axis direction) refers to a vertical direction in the drawing, and the third direction (Z-axis direction) refers to an upper and lower direction in the drawing, that is, a thickness direction. In the following specification, unless otherwise specified, the “direction” may refer to both directions extended along the direction. In addition, when it is necessary to distinguish both “directions” extended to both sides, one side will be referred to as “one side direction” and the other side will be referred to as “other side direction”, respectively. Based on FIG. 1, a direction toward which an arrow indicating a direction is directed will be referred to as one side, and its opposite direction will be referred to as the other side.

Hereinafter, for convenience of description, when referring to the display device 10 or surfaces of each member constituting the display device 10, a direction in which an image is displayed, that is, one surface directed toward one side in the third direction (Z-axis direction) will be referred to as an upper surface, and its opposite surface will be referred to as the other surface, but the present disclosure is not limited thereto. The one surface and the other surface of the member may be referred to as a front surface and a rear surface, respectively, or may be referred to as a first surface or a second surface. In addition, in describing a relative position of each member of the display device 10, one side in the third direction (Z-axis direction) may be referred to as an upper portion, and the other side in the third direction (Z-axis direction) may be referred to as a lower portion.

Various modifications may be made in a shape of the display device 10. For example, the display device 10 may have a shape such as a rectangle of a long width, a rectangle of a long length, a square, a rectangle of round corners (vertexes), other polygons and a circle.

The display device 10 may include a display panel 100, a display driver 200, a circuit board 300, and a touch driver 400.

The display panel 100 may include a main area MA and a sub-area SBA. The main area MA may include a display area DA including pixels for displaying an image, and a non-display area NDA disposed near the display area DA. The main area MA and the sub-area SBA may include a flexible material capable of being subjected to bending, folding, rolling and the like.

The display area DA is an area in which a screen may be displayed, and the non-display area NDA is an area in which a screen is not displayed. The display area DA may be referred to as an active area, and the non-display area NDA may be referred to as a non-active area. The display area DA may generally occupy the center of the display device 10. The non-display area NDA may be an outer area of the display area DA. The non-display area NDA may be defined as an edge area of the main area MA of the display panel 100. The non-display area NDA may include lines for supplying a signal to the display area DA, and lines for connecting the display driver 200 with the display area DA.

The sub-area SBA may be extended from one side of the main area MA. When the sub-area SBA is bent, the sub-area SBA may overlap the main area MA in the thickness direction (e.g., the third direction (Z-axis direction)). The sub-area SBA may include a display pad connected to the display driver 200 and the circuit board 300. In another embodiment, the sub-area SBA may be omitted, and the display driver 200 and the display pad may be disposed in the non-display area NDA.

The display driver 200 may output signals and voltages for driving the display panel 100. The display driver 200 may be formed of an integrated circuit (“IC”), and may be packaged on the display panel 100 by a chip on glass (“COG”) method, a chip on plastic (“COP”) method or an ultrasonic bonding method. For example, the display driver 200 may be disposed in the sub-area SBA, and may overlap the main area MA in the thickness direction by bending of the sub-area SBA. For another example, the display driver 200 may be packaged on the circuit board 300.

The circuit board 300 may be attached onto the display pad of the display panel 100 by using an anisotropic conductive film (“ACF”). The circuit board 300 may be electrically connected to the display pad. The circuit board 300 may be a flexible printed circuit board, a printed circuit board, or a flexible film such as a chip on film.

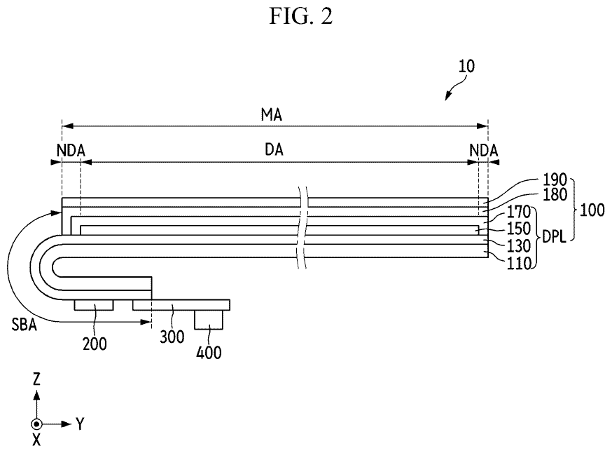

The touch driver 400 may be packaged on the circuit board 300. The touch driver 400 may be connected to a touch sensor layer (‘180’ of FIG. 2) of the display panel 100.

FIG. 2 is a schematic cross-sectional view of the display device of FIG. 1.

Referring to FIG. 2, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate capable of being subjected to bending, folding, rolling or the like. For example, the substrate 110 may include a polymer resin such as polyimide (“PI”), but is not limited thereto. In another embodiment, the substrate 110 may include a glass material or a metal material.

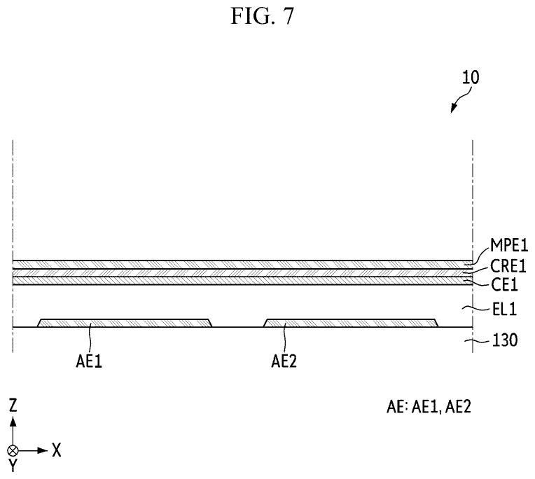

The thin film transistor layer 130 may be positioned on the substrate 110. The thin film transistor layer 130 may be positioned at a portion that overlaps the display area DA, the non-display area NDA, and the sub-area SBA. The thin film transistor layer 130 may include a plurality of thin film transistors (‘TFT’ of FIG. 7).

The display element layer 150 may be positioned on the thin film transistor layer 130. The display element layer 150 may be positioned at a portion that overlaps the display area DA. The display element layer 150 may include at least one of an organic light emitting diode including an organic light emitting layer, a quantum dot light emitting diode (“LED”) including a quantum dot light emitting layer, an inorganic light emitting diode including an inorganic semiconductor, or a micro light emitting diode (Micro LED), but is not limited thereto.

The thin film encapsulation layer 170 may be positioned on the display element layer 150. The thin film encapsulation layer 170 may be positioned at a portion that overlaps the display area DA and the non-display area NDA. The thin film encapsulation layer 170 may cover an upper surface and sides of the display element layer 150, and may protect the display element layer 150 from external oxygen and moisture. The thin film encapsulation layer 170 may include at least one inorganic layer and at least one organic layer to encapsulate the display element layer 150.

The touch sensor layer 180 may be disposed on the thin film encapsulation layer 170. The touch sensor layer 180 may be positioned at a portion that overlaps the display area DA and the non-display area NDA. The touch sensor layer 180 may sense a user's touch in a mutual capacitance manner or a self-capacitance manner.

The color filter layer 190 may be positioned on the touch sensor layer 180. The color filter layer 190 may be positioned at a portion that overlaps the display area DA and the non-display area NDA. The color filter layer 190 may reduce reflective light due to external light by absorbing a portion of light introduced from the outside of the display device 10. Therefore, the color filter layer 190 may prevent color distortion due to reflection of external light from occurring.

As the color filter layer 190 is directly disposed on the touch sensor layer 180, the display device 10 may not require a separate substrate for the color filter layer 190. Therefore, a thickness of the display device 10 may be relatively small. In addition, the color filter layer 190 may be omitted depending on the embodiment.

As shown in FIG. 2, a portion of the display layer DPL overlapped with the sub-area SBA may be bent. When a portion of the display layer DPL is bent, the display driver 200, the circuit board 300 and the touch driver 400 may overlap the main area MA in the third direction (Z-axis direction).

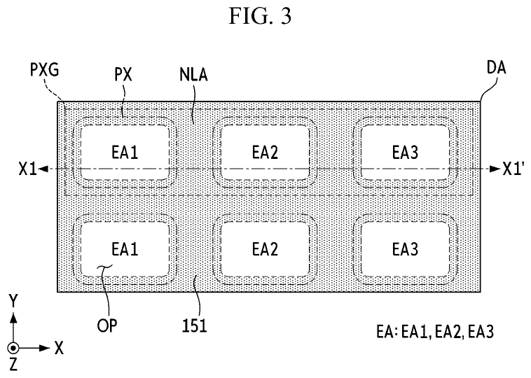

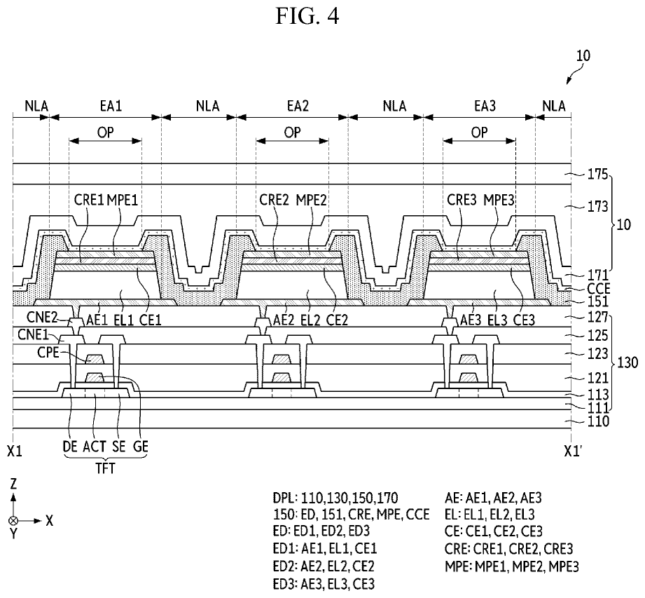

FIG. 3 is a plan view illustrating an arrangement of a light emission area in the display area of FIG. 2. As used herein, the “plan view” is a view in a thickness direction (i.e., Z-axis direction) of the substrate 110 (See FIG. 4).

Referring to FIG. 3, the display area DA according to one embodiment may include a plurality of first to third light emission areas EA1, EA2 and EA3 and a non-light emission area NLA. The non-light emission area NLA may be positioned to surround each of the plurality of first to third light emission areas EA1, EA2 and EA3.

The non-light emission area NLA may shield light emitted from each of the plurality of first to third emission areas EA1, EA2 and EA3. For this reason, the non-light emission area NLA may assist so that the light emitted from the plurality of first to third emission areas EA1, EA2 and EA3 may not be mixed.

The light emission area EA may include a first light emission area EA1, a second light emission area EA2 and a third light emission area EA3, which emit light of different colors. Each of the first to third light emission areas EA1, EA2 and EA3 may emit red, green or blue light, and the color of light emitted from each of the first to third light emission areas EA1, EA2 and EA3 may be different depending on a type of a light emitting element ED that will be described later. Although the first to third light emission areas EA1, EA2 and EA3 are shown as having the same size and shape, the present disclosure is not limited thereto. The size and shape of each of the first to third light emission areas EA1, EA2 and EA3 may be freely adjusted depending on required characteristics.

At least one first light emission area EA1, at least one second light emission area EA2 and at least one third light emission area EA3, which are disposed to be adjacent to one another, may constitute one pixel group PXG. The pixel group PXG may be a minimum unit for emitting white light. However, various modifications may be made in the type and/or number of the first to third light emission areas EA1, EA2 and EA3 constituting the pixel group PXG depending on the embodiments.

In a plan view, a pixel defining layer 151 may be positioned at a portion that overlaps a portion of the light emission area EA and the non-light emission area NLA. In a plan view, the pixel defining layer 151 may define an opening OP therein. In a plan view, the pixel defining layer 151 may be positioned to surround the opening OP.

FIG. 4 is a schematic cross-sectional view taken along line X1-X1′ of FIG. 3. FIG. 4 is a partial cross-sectional view of a display device that overlaps the display area of FIG. 3, and illustrates a schematic cross-section of a display layer. That is, FIG. 4 illustrates cross-sections of a substrate, a thin film transistor layer, a display element layer and a thin film encapsulation layer, which are positioned at a portion that overlaps a display area (DA of FIG. 3) included in the display device 10. Since the substrate 110 has been already described, its description will be omitted.

Referring to FIG. 4, the thin film transistor layer 130 may be positioned on the substrate 110. The thin film transistor layer 130 may include a first buffer layer 111, a thin film transistor TFT, a gate insulating layer 113, a first interlayer insulating layer 121, a capacitor electrode CPE, a second interlayer insulating layer 123, a first connection electrode CNE1, a first via-layer 125, a second connection electrode CNE2, and a second via-layer 127.

The first buffer layer 111 may be positioned on the substrate 110. The first buffer layer 111 may include an inorganic layer capable of preventing permeation of the air or moisture. For example, the first buffer layer 111 may include a plurality of inorganic layers that are alternately stacked.

The thin film transistor TFT may be disposed on the first buffer layer 111, and may constitute a pixel circuit connected to each of the pixels. For example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be disposed on the first buffer layer 111. The active layer ACT may overlap the gate electrode GE in the third direction (Z-axis direction), and may be insulated from the gate electrode GE by the gate insulating layer 113. A material of the active layer ACT may be conductorized so that a portion of the active layer ACT may form the source electrode SE and the drain electrode DE.

The gate electrode GE may be positioned on the gate insulating layer 113. The gate electrode GE may overlap the active layer ACT with the gate insulating layer 113 interposed therebetween.

The gate insulating layer 113 may be positioned on the active layer ACT. The gate insulating layer 113 may cover the active layer ACT and the first buffer layer 111, and may insulate the active layer ACT from the gate electrode GE. The gate insulating layer 113 may include a contact hole through which the first connection electrode CNE1 passes.

The first interlayer insulating layer 121 may cover the gate electrode GE and the gate insulating layer 113. The first interlayer insulating layer 121 may include a contact hole through which the first connection electrode CNE1 passes. The contact hole of the first interlayer insulating layer 121 may be connected to a contact hole of the gate insulating layer 113 and a contact hole of the second interlayer insulating layer 123.

The capacitor electrode CPE may be positioned on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode CNE1 passes. The contact hole of the second interlayer insulating layer 123 may be connected to the contact hole of the first interlayer insulating layer 121 and the contact hole of the gate insulating layer 113.

The first connection electrode CNE1 may be positioned on the second interlayer insulating layer 123. The first connection electrode CNE1 may electrically connect the drain electrode DE of the thin film transistor TFT to the second connection electrode CNE2. The first connection electrode CNE1 may be inserted into the contact holes formed in the first interlayer insulating layer 121, the second interlayer insulating layer 123 and the gate insulating layer 113, and thus may be in contact with the drain electrode DE of the thin film transistor TFT.

The first via-layer 125 may cover the first connection electrode CNE1 and the second interlayer insulating layer 123. The first via-layer 125 may planarize a lower structure. The first via-layer 125 may include a contact hole through which the second connection electrode CNE2 passes.

The second connection electrode CNE2 may be positioned on the first via-layer 125. The second connection electrode CNE2 may be inserted into the contact hole formed in the first via-layer 125 to contact the first connection electrode CNE1. The second connection electrode CNE2 may electrically connect the first connection electrode CNE1 to first to third anode electrodes AE1, AE2 and AE3.

The second via-layer 127 may cover the second connection electrode CNE2 and the first via-layer 125. The second via-layer 127 may include a contact hole through which the first to third anode electrodes AE1, AE2 and AE3 pass.

The display element layer 150 may be positioned on the second via-layer 127. The display element layer 150 may include a light emitting element ED, a pixel defining layer 151, an oxidation protective electrode CRE, a moisture-permeable protective electrode MPE, and a common electrode CCE. Hereinafter, the oxidation protective electrode CRE and the moisture-permeable protective electrode MPE may be commonly used as protective electrodes.

The light emitting element ED of one embodiment may include an anode electrode AE, a light emitting layer EL, and a cathode electrode CE. The light emitting element ED may include a first light emitting element ED1 disposed in the first light emission area EA1, a second light emitting element ED2 disposed in the second light emission area EA2, and a third light emitting element ED3 disposed in the third light emission area EA3.

The light emitting element ED that overlaps each of the first to third light emission areas EA1, EA2 and EA3 may emit light of different colors depending on the material of the light emitting layer EL. For example, the first light emitting element ED1 may emit red light, the second light emitting element ED2 may emit green light, and the third light emitting element ED3 may emit blue light.

The anode electrode AE of one embodiment may be positioned on the second via-layer 127. The anode electrode AE may be electrically connected to the drain electrode DE of the thin film transistor TFT through the first connection electrode CNE1 and the second connection electrode CNE2.

The anode electrode AE may include a first anode electrode AE1 disposed in the first light emission area EA1, a second anode electrode AE2 disposed in the second light emission area EA2, and a third anode electrode AE3 disposed in the third light emission area EA3. The first anode electrode AE1, the second anode electrode AE2 and the third anode electrode AE3 may be disposed to be spaced apart from one another on the second via-layer 127.

The anode electrode AE of one embodiment may have a stacked layer structure in which a material layer, which has a high work function, such as indium tin oxide (“ITO”), indium zinc oxide (“IZO”), zinc oxide (ZnO) and indium oxide (In₂O₃), and a reflective material layer such as Ag, Mg, Al, Pt, Pb, Pd, Au, Ni, Nd, Ir, Cr, Li, Ca or their mixture are stacked. For example, the anode electrode AE may have a multi-layered structure of ITO/Mg, ITO/MgF, ITO/Ag, and ITO/Ag/ITO, but is not limited thereto.

The light emitting layer EL of one embodiment may be positioned on the anode electrode AE. The light emitting layer EL may include a first light emitting layer EL1, a second light emitting layer EL2 and a third light emitting layer EL3, which are respectively disposed in the first to third light emission areas EA1, EA2 and EA3. The first light emitting layer EL1, the second light emitting layer EL2 and the third light emitting layer EL3 may emit light of different colors. For example, the first light emitting layer EL1 may emit red light, the second light emitting layer EL2 may emit green light and the third light emitting layer EL3 may emit blue light, but the present disclosure is not limited thereto.

The light emitting layer EL according to one embodiment may be formed through a photo pattern (photo lithography) process in a fabricating process. In other words, the light emitting layer EL may be formed through a photo process and an etching process without using a separate fine metal mask. The fabricating process will be described later.

The cathode electrode CE according to one embodiment may be positioned on the light emitting layer EL. The cathode electrode CE according to one embodiment may be integrally formed with the light emitting layer EL. The cathode electrode CE may include a first cathode electrode CE1, a second cathode electrode CE2 and a third cathode electrode CE3, which are respectively disposed in the first to third light emission areas EA1, EA2 and EA3. The first cathode electrode CE1, the second cathode electrode CE2 and the third cathode electrode CE3 may be spaced apart from one another with the pixel defining layer 151 interposed therebetween.

The cathode electrode CE may receive a common voltage or a low potential voltage. In detail, when the anode electrode AE receives a voltage corresponding to a data voltage and the cathode electrode CE receives a low potential voltage, a potential difference is formed between the anode electrode AE and the cathode electrode CE and thus light may be emitted from the light emitting layer EL.

The cathode electrode CE may be formed in the form shown in FIG. 4 through the same photo pattern process as the photo pattern process of forming the light emitting layer EL during the fabricating process. In other words, the cathode electrode CE may be formed through a photo process and an etching process without using a separate fine metal mask. The fabricating process will be described later.

The oxidation protective electrode CRE according to one embodiment may be positioned on the cathode electrode CE. The oxidation protective electrode CRE may be integrally formed with the cathode electrode CE. The oxidation protective electrode CRE may include a first oxidation protective electrode CRE1, a second oxidation protective electrode CRE2 and a third oxidation protective electrode CRE3, which are respectively disposed in the first to third light emission areas EA1, EA2 and EA3. The first oxidation protective electrode CRE1, the second oxidation protective electrode CRE2 and the third oxidation protective electrode CRE3 may be spaced apart from one another with the pixel defining layer 151 interposed therebetween.

The oxidation protective electrode CRE may protect surfaces of the light emitting layer EL and the cathode electrode CE in the fabricating process.

The oxidation protective electrode CRE may be electrically connected to the cathode electrode CE. The first oxidation protective electrode CRE1 may be electrically connected to the first cathode electrode CE1, the second oxidation protective electrode CRE2 may be electrically connected to the second cathode electrode CE2, and the third oxidation protective electrode CRE3 may be electrically connected to the third cathode electrode CE3.

The oxidation protective electrode CRE may be formed in the form shown in FIG. 4 through the same photo pattern process as the photo pattern process of forming the light emitting layer EL and the cathode electrode CE without using a separate fine metal mask in the fabricating process. The fabricating process will be described later.

The moisture-permeable protective electrode MPE according to one embodiment may be positioned on the oxidation protective electrode CRE. The moisture-permeable protective electrode MPE may include a first moisture-permeable protective electrode MPE1, a second moisture-permeable protective electrode MPE2 and a third moisture-permeable protective electrode MPE3, which are respectively disposed in the first to third light emission areas EA1, EA2 and EA3. The first moisture-permeable protective electrode MPE1, the second moisture-permeable protective electrode MPE2 and the third moisture-permeable protective electrode MPE3 may be spaced apart from one another with the pixel defining layer 151 interposed therebetween. However, the moisture-permeable protective electrode MPE may be omitted depending on the embodiment.

The moisture-permeable protective electrode MPE may resolve a damage defect of the light emitting layer EL and the cathode electrode CE in the fabricating process.

The moisture-permeable protective electrode MPE may be electrically connected to the cathode electrode CE through the oxidation protective electrode CRE. The first moisture-permeable protective electrode MPE1 may be electrically connected to the first cathode electrode CE1 through the first oxidation protective electrode CRE1, the second moisture-permeable protective electrode MPE2 may be electrically connected to the second cathode electrode CE2 through the second oxidation protective electrode CRE2, and the third moisture-permeable protective electrode MPE3 may be electrically connected to the third cathode electrode CE3 through the third oxidation protective electrode CRE3.

The moisture-permeable protective electrode MPE may be formed in the form shown in FIG. 4 through the same photo pattern process as the photo pattern process of forming the light emitting layer EL and the cathode electrode CE without using a separate fine metal mask in the fabricating process. The fabricating process will be described later.

The pixel defining layer 151 according to one embodiment may be positioned at a portion overlapping the non-light emission area NLA. The pixel defining layer 151 may be positioned on the second via-layer 127, the anode electrode AE and the moisture-permeable protective electrode MPE.

The pixel defining layer 151 may separate and insulate each of the first to third light emitting elements ED1, ED2 and ED3, may separate and insulate each of the first to third oxidation protective electrodes CRE1, CRE2 and CRE3, and may separate and insulate each of the first to third moisture-permeable protective electrodes MPE1, MPE2 and MPE3.

The pixel defining layer 151 may define the opening OP. The pixel defining layer 151 may expose the opening OP and surround edges of the light emitting element ED, the oxidation protective electrode CRE and the moisture-permeable protective electrode MPE.

The common electrode CCE according to one embodiment may be positioned on the moisture-permeable protective electrode MPE. The common electrode CCE may be in contact with each of the first moisture-permeable protective electrode MPE1, the second moisture-permeable protective electrode MPE2 and the third moisture-permeable protective electrode MPE3, and may electrically connect the first moisture-permeable protective electrode MPE1, the second moisture-permeable protective electrode MPE2 and the third moisture-permeable protective electrode MPE3 with one another.

The common electrode CCE may electrically connect the first cathode electrode CE1, the second cathode electrode CE2 and the third cathode electrode CE3, which are spaced apart from one another, with one another. In detail, the first cathode electrode CE1 may be connected to the common electrode CCE through the first oxidation protective electrode CRE1 and the first moisture-permeable protective electrode MPE1, and the second cathode electrode CE2 may be connected to the common electrode CCE through the second oxidation protective electrode CRE2 and the second moisture-permeable protective electrode MPE2, and the third cathode electrode CE3 may be connected to the common electrode CCE through the third oxidation protective electrode CRE3 and the third moisture-permeable protective electrode MPE3.

The thin film encapsulation layer 170 according to one embodiment may be positioned on the display element layer 150. The thin film encapsulation layer 170 may be positioned at a portion that overlaps the light emission area EA and the non-light emission area NLA. The thin film encapsulation layer 170 may include a first encapsulation layer 171, a second encapsulation layer 173 and a third encapsulation layer 175, which are sequentially stacked.

The first encapsulation layer 171 may be positioned on the common electrode CCE. The first encapsulation layer 171 has a uniform thickness depending on a profile of a lower structure, and may cover the lower structure. Therefore, the first encapsulation layer 171 may include a step difference.

The first encapsulation layer 171 may include one or more inorganic insulating materials, and may prevent oxygen or moisture from being permeated into the light emitting element ED. For example, the first encapsulation layer 171 may include at least one of aluminum oxide, titanium oxide, tantalum oxide, hafnium oxide, zinc oxide, silicon oxide, silicon nitride or silicon oxynitride.

The second encapsulation layer 173 may be positioned on the first encapsulation layer 171. The second encapsulation layer 173 may planarize a step difference formed by the first encapsulation layer 171. In addition, the second encapsulation layer 173 may protect the display element layer 150 from particles.

The second encapsulation layer 173 may include a polymer-based material. For example, the second encapsulation layer 173 may include a silicon-based resin, an acrylic-based resin, an epoxy-based resin and their mixture.

The third encapsulation layer 175 may be positioned on the second encapsulation layer 173. The third encapsulation layer 175 may include one or more inorganic insulating materials, and may prevent oxygen or moisture from being permeated into the display element layer 150 and the first encapsulation layer 171. The third encapsulation layer 175 may include the same material as the material of the first encapsulation layer 171. A redundant description will be omitted.

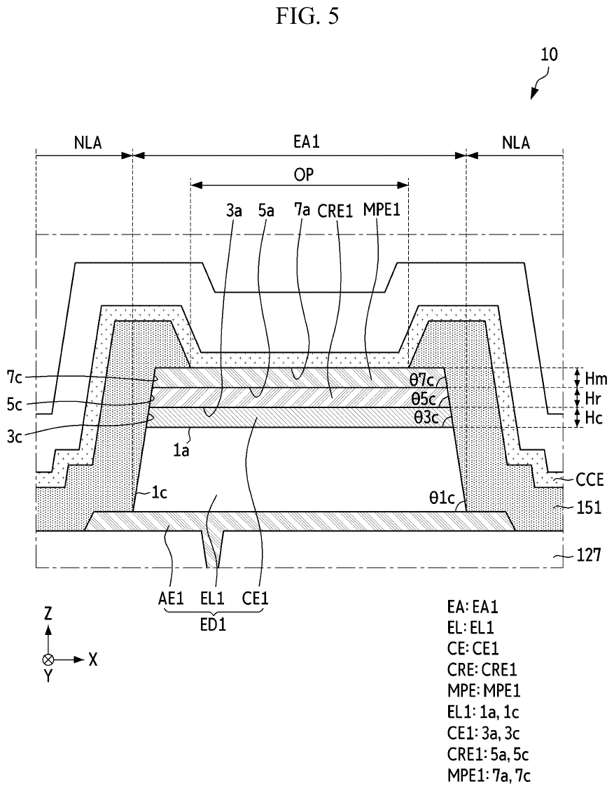

FIG. 5 is a schematic enlarged cross-sectional view illustrating a display element layer that overlaps a first light emission area in FIG. 4.

Referring to FIG. 5, the first light emitting layer EL1 may include an upper surface 1a and a side surface 1c. The upper surface 1a may be one surface facing the first cathode electrode CE1, and the side surface 1c may be one surface facing the non-light emission area NLA. The upper surface 1a and the side surface 1c may be connected to each other.

The side surface 1c of the first light emitting layer EL1 may be an inclined surface. The side surface 1c of the first light emitting layer EL1 may have a high taper angle. For example, a first inclination angle θ1c of the side surface 1c of the first light emitting layer EL1 with respect to an upper surface of the first anode electrode AE1 may have a range from 60° to 90°.

As described above, since the light emitting layer EL is formed by a photo pattern process without using a separate mask, the first light emitting layer EL1 may have a clear side surface 1c without a tail defect caused by a mask shadow.

The upper surface la of the first light emitting layer EL1 may be in contact with the first cathode electrode CE1, and may be covered by the first cathode electrode CE1.

The first cathode electrode CE1 according to one embodiment may be positioned on the first light emitting layer EL1. The first cathode electrode CE1 and the first light emitting layer EL1 may be integrally formed. The first cathode electrode CE1 may not be in contact with the side surface 1c of the first light emitting layer EL1. In other words, first cathode electrode CE1 may not extend to cover the side surface 1c of the first light emitting layer EL1.

The first cathode electrode CE1 may include an upper surface 3a and a side surface 3c. The upper surface 3a may be one surface facing the first oxidation protective electrode CRE1, and the side surface 3c may be one surface facing the non-light emission area NLA. The upper surface 3a and the side surface 3c may be connected to each other.

The side surface 3c of the first cathode electrode CE1 may be an inclined surface. In addition, the side surface 3c of the first cathode electrode CE1 may be aligned in the same line as the side surface 1c of the first light emitting layer EL1, but is not limited thereto.

The side surface 3c of the first cathode electrode CE1 may have a high taper angle. For example, a second inclination angle θ3c of the side surface 3c of the first cathode electrode CE1 with respect to the upper surface 1a of the first light emitting layer EL1 may have a range from 60° to 90°.

As described above, since the cathode electrode CE is formed by a photo pattern process without using a separate mask, the first cathode electrode CE1 may have a clear side surface 3c without a tail defect caused by a mask shadow.

The upper surface 3a of the first cathode electrode CE1 may be in contact with the first oxidation protective electrode CRE1, and may be covered by the first oxidation protective electrode CRE1.

The cathode electrode CE may include metal oxide. For example, the cathode electrode CE may include at least one of ytterbium oxide (Yb₂O₃) or terbium oxide (Tb₂O₃). Ytterbium oxide (Yb₂O₃) or terbium oxide (Tb₂O₃) may be a material having excellent oxidation resistance.

In the display device 10 of one embodiment, since the cathode electrode CE includes metal oxide, a process of forming the cathode electrode CE may be performed by the same photo pattern process as that performed for a process of forming the light emitting layer EL. That is, the display device 10 may have easiness in fabrication.

In some embodiments, a thickness Hc of the cathode electrode CE measured in the Z-axis direction may have a value of 5Å or more and 15Å or less.

The first oxidation protective electrode CRE1 of one embodiment may be positioned on the first cathode electrode CE1. The first oxidation protective electrode CRE1 and the first cathode electrode CE1 may be integrally formed. The first oxidation protective electrode CRE1 may not be in contact with the side surface 3c of the first cathode electrode CE1. In other words, the first oxidation protective electrode CRE1 may not extend to cover the side surface 3c of the first cathode electrode CE1.

The first oxidation protective electrode CRE1 may include an upper surface 5a and a side surface 5c. The upper surface 5a may be one surface facing the first moisture-permeable protective electrode MPE1, and the side surface 5c may be one surface facing the non-light emission area NLA. The upper surface 5a and the side surface 5c may be connected to each other.

The side surface 5c of the first oxidation protective electrode CRE1 may be an inclined surface. The side surface 5c of the first oxidation protective electrode CRE1 may be aligned in the same line as the side surface 3c of the first cathode electrode CE1, but is not limited thereto.

The side surface 5c of the first oxidation protective electrode CRE1 may have a high taper angle. For example, a third inclination angle 05c of the side surface 5c of the first oxidation protective electrode CRE1 with respect to the upper surface 3a of the first cathode electrode CE1 may have a range from 60° to 90°.

As described above, since the oxidation protective electrode CRE is formed by a photo pattern process without using a separate mask, the first oxidation protective electrode CRE1 may have a clear side surface 5c without a tail defect caused by a mask shadow.

The upper surface 5a of the first oxidation protective electrode CRE1 may be in contact with the first moisture-permeable protective electrode MPE1, and may be covered by the first oxidation protective electrode CRE1.

The oxidation protective electrode CRE may include Ag-alloy metal having chemical resistance properties. For example, the oxidation protective electrode CRE may include at least one of Ag—Bi alloy or Ag—Sb alloy. The oxidation protective electrode CRE according to one embodiment includes Ag-alloy metal having chemical resistance properties, thereby resolving a damage defect of the light emitting layer EL and the cathode electrode CE by an etching process.

In some embodiments, a thickness Hr of the oxidation protective electrode CRE measured in the Z-axis direction may be 80Å or more and 150Å or less.

The first moisture-permeable protective electrode MPE1 according to one embodiment may be positioned on the first oxidation protective electrode CRE1. The first moisture-permeable protective electrode MPE1 and the first oxidation protective electrode CRE1 may be integrally formed. The first moisture-permeable protective electrode MPE1 may not be in contact with the side surface 5c of the first oxidation protective electrode CRE1. In other words, the first moisture-permeable protective electrode MPE1 may not extend to cover the side surface 5c of the first oxidation protective electrode CRE1.

The first moisture-permeable protective electrode MPE1 may include an upper surface 7a and a side surface 7c. The upper surface 7a may be a surface that is in contact with the common electrode CCE, and the side surface 7c may be a surface facing the non-light emission area NLA. The upper surface 7a and the side surface 7c may be connected to each other.

The side surface 7c of the first moisture-permeable protective electrode MPE1 may be an inclined surface. The side surface 7c of the first moisture-permeable protective electrode MPE1 may be aligned in the same line as the side surface 5c of the first oxidation protective electrode CRE1, but is not limited thereto.

The side surface 7c of the first moisture-permeable protective electrode MPE1 may have a high taper angle. For example, a fourth inclination angle θ7c of the side surface 7c of the first moisture-permeable protective electrode MPE1 with respect to the upper surface 5a of the first oxidation protective electrode CRE1 may have a range from 60° to 90°.

As described above, since the moisture-permeable protective electrode MPE is formed by a photo pattern process without using a separate mask, the first moisture-permeable protective electrode MPE1 may have a clear side surface 7c without a tail defect caused by a mask shadow.

The upper surface 7a of the first moisture-permeable protective electrode MPE1 may be in contact with the common electrode CCE and the pixel defining layer 151, and may be covered by the common electrode CCE and the pixel defining layer 151.

The moisture-permeable protective electrode MPE may include a transparent oxide electrode TCO. For example, the moisture-permeable protective electrode MPE may include at least one of indium-tin-oxide (ITO), indium-zinc-oxide (IZO) or zinc-indium-tin-oxide (“ZITO”). The moisture-permeable protective electrode MPE according to one embodiment includes a transparent oxide electrode TCO having anti-moisture-permeable properties, thereby resolving a damage defect of the light emitting layer EL and the cathode electrode CE, which is caused in the fabricating process.

In some embodiments, a thickness Hm of the moisture-permeable protective electrode MPE measured in the Z-axis direction may have a value of 70Å or more and 300Å or less.

The pixel defining layer 151 according to one embodiment may surround the opening OP, and may be positioned on the first moisture-permeable protective electrode MPE1. The pixel defining layer 151 may expose the moisture-permeable protective electrode MPE at a portion that overlaps the light emission area EA. The pixel defining layer 151 may be in contact with the upper surface 7a and the side surface 7c of the first moisture-permeable protective electrode MPE1, and may completely cover the side surface 7c of the first moisture-permeable protective electrode MPE1.

In addition, the pixel defining layer 151 may be in contact with the side surface 5c of the first oxidation protective electrode CRE1, the side surface 3c of the first cathode electrode CE1 and the side surface 1c of the first light emitting layer EL1, and may completely cover the side surface 5c of the first oxidation protective electrode CRE1, the side surface 3c of the first cathode electrode CE1 and the side surface 1c of the first light emitting layer EL1.

The pixel defining layer 151 may transmit light emitted from the light emitting element ED without blocking light.

The pixel defining layer 151 may include an inorganic insulating material. For example, the pixel defining layer 151 may include at least one of aluminum oxide, titanium oxide, tantalum oxide, hafnium oxide, zinc oxide, silicon oxide, silicon nitride or silicon oxynitride.

The common electrode CCE according to one embodiment may be in contact with the first moisture-permeable protective electrode MPE1 at a portion that overlaps the opening OP. The common electrode CCE may be formed at a portion that overlaps the light emission area EA and the non-light emission area NLA to have a uniform thickness along a profile formed by the pixel defining layer 151 and the moisture-permeable protective electrode MPE.

The common electrode CCE may include a transparent oxide electrode TCO. For example, the common electrode CCE may include indium-tin-oxide (ITO), indium-zinc-oxide (IZO), zinc-tin-oxide (“ZTO”), and zinc-indium-tin-oxide (ZITO).

For convenience of description, although the display element layer 150 positioned at a portion overlapped with the first light emission area EA1 has been described with reference to the drawing, a structure and characteristics of the display element layer 150 positioned at a portion overlapped with the second light emission area EA2 and the third light emission area EA3 may be the same as a structure and characteristics of the display element layer 150 positioned at a portion overlapped with the first light emission area EA1.

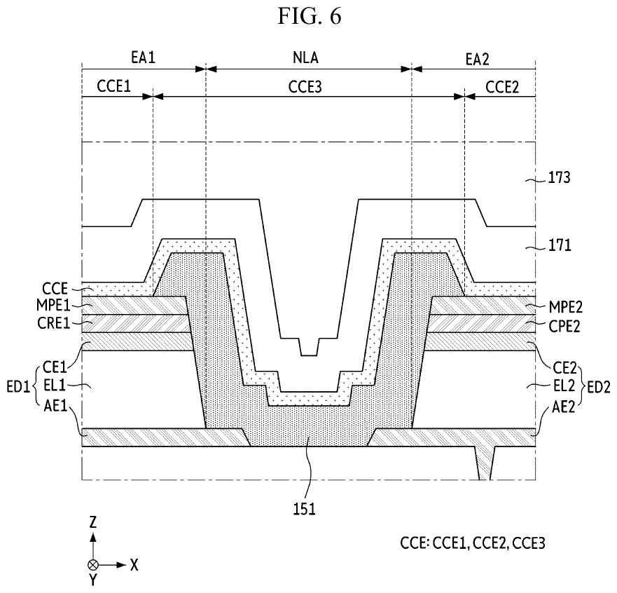

FIG. 6 is a schematic enlarged cross-sectional view illustrating a display element layer that overlaps a non-light emission area positioned between a first light emission area and a second light emission area in FIG. 4.

Referring to FIG. 6, the first light emitting element ED1 and the second light emitting element ED2 may be spaced apart from each other in the first direction (X-axis direction) with the pixel defining layer 151 interposed therebetween. The first light emitting layer EL1 and the first cathode electrode CE1, which are included in the first light emitting element ED1, and the second light emitting layer EL2 and the second cathode electrode CE2, which are included in the second light emitting element ED2, may not overlap the non-light emission area NLA.

The first oxidation protective electrode CRE1 and the second oxidation protective electrode CRE2 may be spaced apart from each other in the first direction (X-axis direction) with the pixel defining layer 151 interposed therebetween. The common electrode CCE may be positioned between the first oxidation protective electrode CRE1 and the second oxidation protective electrode CRE2 in the first direction (X-axis direction). The first oxidation protective electrode CRE1 and the second oxidation protective electrode CRE2 may not overlap the non-light emission area NLA.

The first moisture-permeable protective electrode MPE1 and the second moisture-permeable protective electrode MPE2 may be spaced apart from each other in the first direction (X-axis direction) with the pixel defining layer 151 interposed therebetween. The common electrode CCE may be positioned between the first moisture-permeable protective electrode MPE1 and the second moisture-permeable protective electrode MPE2 in the first direction (X-axis direction). The first moisture-permeable protective electrode MPE1 and the second moisture-permeable protective electrode MPE2 may not overlap the non-light emission area NLA.

In some embodiments, the common electrode CCE may include a first portion CCE1, a second portion CCE2 and a third portion CCE3 depending on a contact structure. The first portion CCE1 may be a portion that is in contact with the first moisture-permeable protective electrode MPE1, the second portion CCE2 may be a portion that is in contact with the second moisture-permeable protective electrode MPE2, and the third portion CCE3 may be a portion that is in contact with the pixel defining layer 151.

The first portion CCE1 and the second portion CCE2 of the common electrode CCE may be spaced apart from each other with the third portion CCE3 interposed therebetween, and the first portion CCE1, the second portion CCE2 and the third portion CCE3 may be integrally formed. That is, the first portion CCE1 and the second portion CCE2 may be extended from the third portion CCE3.

The first cathode electrode CE1 may be electrically connected to the first part CCE1 of the common electrode CCE through the first oxidation protective electrode CRE1 and the first moisture-permeable protective electrode MPE1, and the second cathode electrode CE2 may be electrically connected to the second portion CCE2 of the common electrode CCE through the second oxidation protective electrode CRE2 and the second moisture-permeable protective electrode MPE2.

The first encapsulation layer 171 according to one embodiment may entirely cover the common electrode CCE, and the second encapsulation layer 173 may planarize a step difference formed by the first encapsulation layer 171. Other redundant description will be omitted.

FIGS. 7 to 16 are cross-sectional views illustrating a method of fabricating a display element layer and a thin film encapsulation layer in FIG. 4. Hereinafter, the order of forming each layer of the display element layer 150 and the thin film encapsulation layer 170 will be described.

Referring to FIG. 7, the plurality of anode electrodes AE are formed on the thin film transistor layer 130. The first anode electrode AE1 and the second anode electrode AE2 may be spaced apart from each other in the first direction (X-axis direction). Although not shown in the drawing, the thin film transistor layer 130 may be disposed on the substrate 110, and the structure of the thin film transistor layer 130 is the same as that described with reference to FIG. 4. A redundant description will be omitted.

Subsequently, the first light emitting layer EL1 is formed on the anode electrode AE. The first light emitting layer EL1 may cover the anode electrode AE and the thin film transistor layer 130. A process of forming the first light emitting layer EL1 according to one embodiment may be performed by a thermal evaporation process. This process may be performed without using a separate mask. Therefore, the first light emitting layer EL1 may entirely cover the anode electrode AE and the thin film transistor layer 130.

Next, the first cathode electrode CE1, the first oxidation protective electrode CRE1 and the first moisture-permeable protective electrode MPE1 may be sequentially stacked on the first light emitting layer EL1. The process of forming the first cathode electrode CE1, the first oxidation protective electrode CRE1 and the first moisture-permeable protective electrode MPE1 according to one embodiment may be performed by a sputtering process. This process may be performed without using a separate mask. Therefore, the first cathode electrode AE1 may entirely cover the first light emitting layer EL1, the first oxidation protective electrode CRE1 may entirely cover the first cathode electrode CE1, and the first moisture-permeable protective electrode MPE1 may entirely cover the first oxidation protective electrode CRE1.

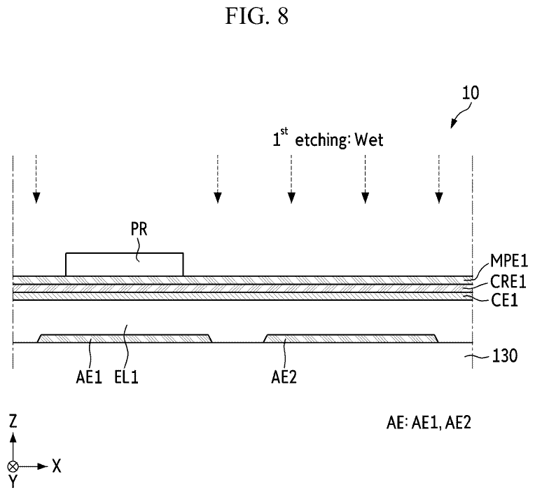

Subsequently, referring to FIGS. 8 to 10, a photoresist PR is formed on the first moisture-permeable protective electrode MPE1, and a first etching process is performed using the photoresist PR as a mask. The photoresist PR may be positioned at a portion that overlaps the first anode electrode AE1. In this process, a wet etching process and a dry etching process may be consecutively performed as the first etching process.

First, the wet etching process of the first etching process may be performed. In the wet etching process, a phosphoric acid-based etching solution may be used.

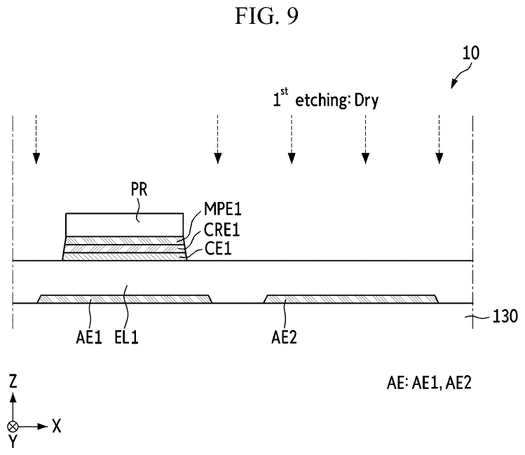

In this process, a portion of the first cathode electrode CE1, a portion of the first oxidation protective electrode CRE1 and a portion of the first moisture-permeable protective electrode MPE1, which do not overlap the photoresist PR, may be simultaneously removed. Therefore, the first cathode electrode CE1, the first oxidation protective electrode CRE1 and the first moisture-permeable protective electrode MPE1 may be formed in the form shown in FIG. 9. In this process, the first light emitting layer EL1 may be exposed without being removed.

Subsequently, the dry etching process of the first etching process may be performed. This process may be performed in a vacuum chamber. In this process, the photoresist PR and the first light emitting layer EL1 may be isotopically removed at the same time. In this process, the photoresist PR may be completely removed, and the first light emitting layer EL1 may remain while entirely covering the first anode electrode AE1 and the second anode electrode AE2.

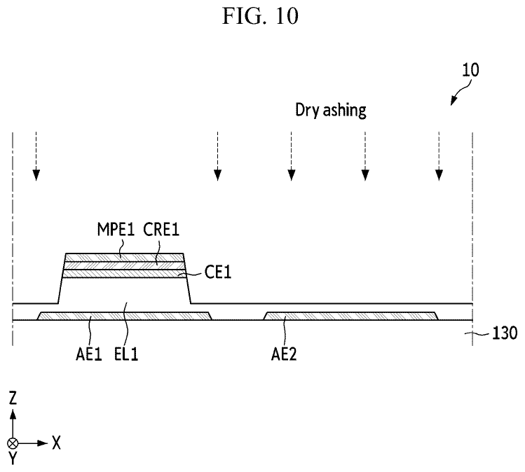

Referring to FIG. 10, a dry ashing process is performed subsequently to the first etching process. This process may be performed in the same vacuum chamber as the dry etching process.

The dry ashing process may be performed without a separate photoresist PR. As described above, the first moisture-permeable protective electrode MPE1 of one embodiment may include a transparent oxide electrode TCO. Therefore, in this process, the first moisture-permeable protective electrode MPE1 may serve as a hard mask even without a separate photoresist PR.

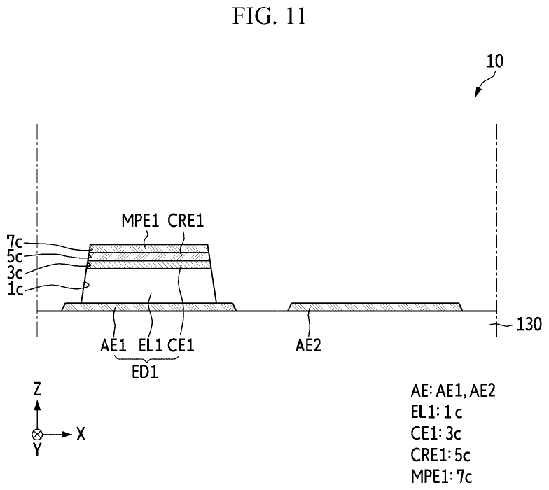

In this process, the lower structures (e.g., the first oxidation protective electrode CRE1, the first cathode electrode CE1 and the first light emitting layer EL1) that overlap the first moisture-permeable protective electrode MPE1 may remain, and a portion of the first light emitting layer EL1 that does not overlap the first moisture-permeable protective electrode MPE1 may be removed, whereby the first light emitting layer EL1 may be formed in the form shown in FIG. 11.

The side surface 1c of the first light emitting layer EL1, the side surface 3c of the first cathode electrode CE1, the side surface 5c of the first oxidation protective electrode CRE1 and the side surface 7c of the first moisture-permeable protective electrode MPE1 may have a clear cross section without a mask tail through the first etching process and the dry etching process.

In addition, each of the side surface 1c of the first light emitting layers EL1, the side surface 3c of the first cathode electrode CE1, the side surface 5c of the first oxidation protective electrode CRE1 and the side surface 7c of the first moisture-permeable protective electrode MPE1 may have a high taper angle.

In some embodiments, the side surface 1c of the first light emitting layers EL1, the side surface 3c of the first cathode electrode CE1, the side surface 5c of the first oxidation protective electrode CRE1 and the side surface 7c of the first moisture-permeable protective electrode MPE1 may be aligned in the same line, but are not limited thereto.

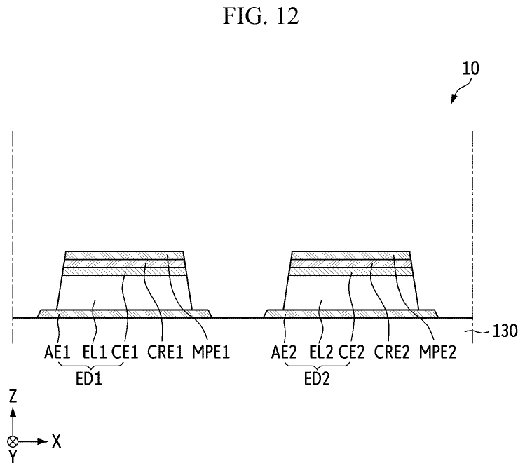

Subsequently, referring to FIG. 12, the above-described process is repeated so that the second light emitting layer EL2, the second cathode electrode CE2, the second oxidation protective electrode CRE2 and the second protective electrode MPE2 are formed on the second anode electrode AE2. A redundant description will be omitted.

In this process, the first light emitting element ED1, the first oxidation protective electrode CRE1 and the first moisture-permeable protective electrode MPE1 may be exposed to the wet etching process, the dry etching process and the dry ashing process. In this case, the first light emitting element ED1 may be protected by the first oxidation protective electrode CRE1 and the first moisture-permeable protective electrode MPE1.

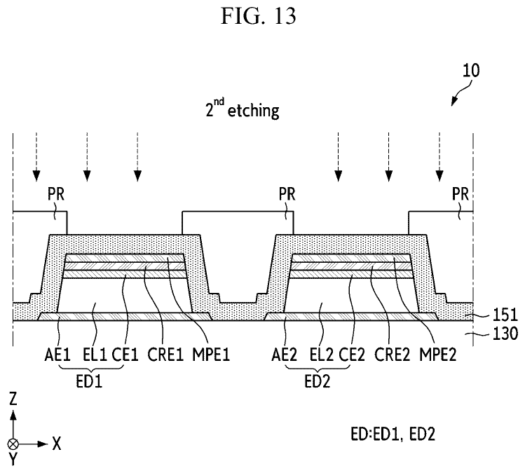

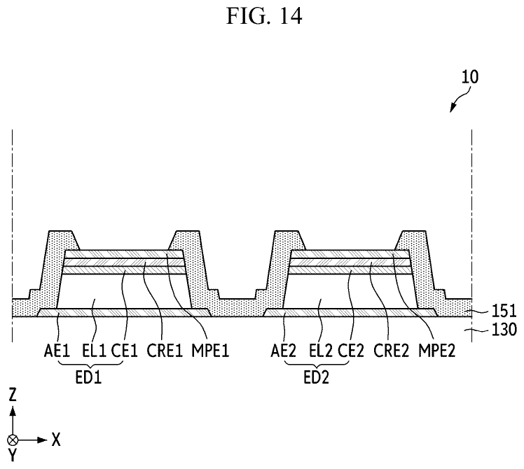

Referring to FIGS. 13 and 14, the pixel defining layer 151 is formed on the first moisture-permeable protective electrode MPE1 and the second moisture-permeable protective electrode MPE2. The process of forming the pixel defining layer 151 may be formed by a thin film deposition process, and this process may be performed in a vacuum chamber.

The pixel defining layer 151 may be formed to entirely cover the first light emitting element ED1, the first oxidation protective electrode CRE1, the first moisture-permeable protective electrode MPE1, the second light emitting element ED2, the second oxidation protective electrode CRE2 and the second moisture-permeable protective electrode MPE2. The pixel defining layer 151 may be in contact with the first anode electrode AE1 and the second anode electrode AE2, and may be also in contact with the thin film transistor layer 130.

Subsequently, the photoresist PR is formed on the pixel defining layer 151 at a portion covering the edge of the light emitting element ED, and a second etching process is performed using the photoresist PR as a mask. As an example, the second etching process may be performed by a dry etching process. This process may be performed in a vacuum chamber.

In this process, the pixel defining layer 151 positioned at a portion where the photoresist PR is not formed may be removed, and the first moisture-permeable protective electrode MPE1 and the second moisture-permeable protective electrode MPE2 may be exposed.

In this process, the first moisture-permeable protective electrode MPE1 and the second moisture-permeable protective electrode MPE2 may serve as hard masks. Therefore, the first light emitting element ED1, the first cathode electrode CE1 and the first oxidation protective electrode CRE1, which are positioned to overlap the first moisture-permeable protective electrode MPE1, may not be removed, and the second light emitting element ED2, the second cathode electrode CE2 and the second oxidation protective electrode CRE2, which are positioned to overlap the second moisture-permeable protective electrode MPE2, may not be removed. In this process, the pixel defining layer 151 may be formed in the form shown in FIG. 14.

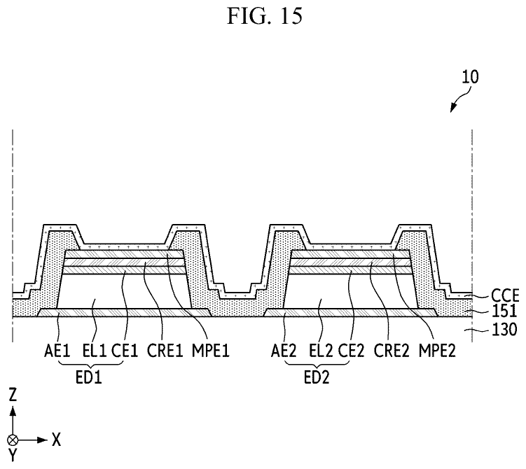

Next, referring to FIG. 15, the common electrode CCE is formed on the first moisture-permeable protective electrode MPE1, the second moisture-permeable protective electrode MPE2 and the pixel defining layer 151. The process of forming the common electrode CCE may be performed by a sputtering process. This process may be performed in a vacuum chamber.

In this process, the first moisture-permeable protective electrode MPE1 and the second moisture-permeable protective electrode MPE2 may be in contact with the common electrode CCE, and the first moisture-permeable protective electrode MPE1 and the second moisture-permeable protective electrode MPE2, which are positioned to be physically spaced apart from each other, may be electrically connected by the common electrode CCE.

In this process, the first oxidation protective electrode CRE1 and the second oxidation protective electrode CRE2 may protect the first cathode electrode CE1 and the second cathode electrode CE2 from a plasma damage caused by sputtering.

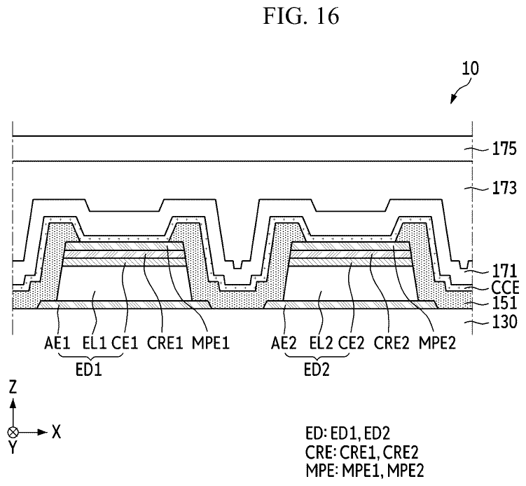

Finally, referring to FIG. 16, the first encapsulation layer 171, the second encapsulation layer 173 and the third encapsulation layer 175 are sequentially stacked on the common electrode CCE, so that the display element layer 150 and the thin film encapsulation layer 170, which are shown in FIG. 4, may be formed.

In the display device 10 according to one embodiment, the light emitting element ED may be formed by the photo pattern process, so that a high-resolution display device may be provided. In addition, the display device 10 of one embodiment may include the oxidation protective electrode CRE and the moisture-permeable protective electrode MPE on the cathode electrode CE, thereby resolving a damage defect of the light emitting element ED, which is caused in the fabricating process of the display device 10.

The display device according to one embodiment of the present disclosure can be applied to various electronic devices. The electronic device according to the one embodiment of the present disclosure includes the display device described above, and may further include modules or devices having additional functions in addition to the display device.

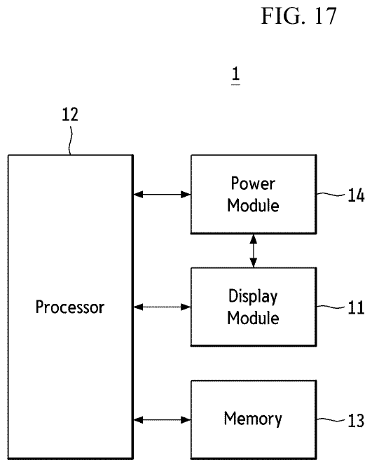

FIG. 17 is a block diagram of an electronic device according to one embodiment of the present disclosure.

Referring to FIG. 17, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

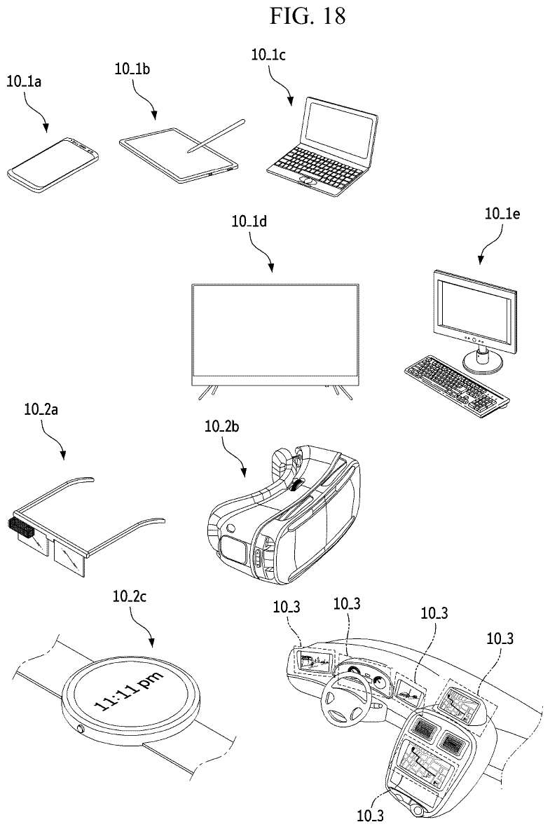

FIG. 18 is a schematic diagram of an electronic device according to various embodiments of the present disclosure.

Referring to FIG. 18, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Although the embodiments of the present disclosure have been described with reference to the accompanying drawings, those skilled in the art would understand that various modifications and alterations may be made without departing from the technical idea or essential features of the present disclosure. Therefore, it should be understood that the above-mentioned embodiments are not limiting but illustrative in all aspects.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a light emission area and a non-light emission area;
an anode electrode positioned on the light emission area of the substrate;
a light emitting layer positioned on the anode electrode;
a cathode electrode positioned on the light emitting layer;
a protective electrode positioned on the cathode electrode;
a pixel defining layer positioned on the non-light emission area of the substrate, and defining an opening therein; and
a common electrode positioned on the pixel defining layer and in contact with the protective electrode at a portion that overlaps the opening,
wherein a first inclination angle of a side surface of the light emitting layer, which faces the non-light emission area, with respect to an upper surface of the anode electrode is 60° to 90°.

2. The display device of claim 1, wherein the cathode electrode includes a side surface facing the non-light emission area, and
a second inclination angle of the side surface of the cathode electrode with respect to an upper surface of the light emitting layer is 60° to 90°.

3. The display device of claim 2, wherein the cathode electrode doesn't cover the side surface of the light emitting layer.

4. The display device of claim 1, wherein the cathode electrode includes metal oxide.

5. The display device of claim 1, wherein the cathode electrode includes at least one of ytterbium oxide (Yb₂O₃) or terbium oxide (Tb₂O₃).

6. The display device of claim 1, wherein a thickness of the cathode electrode in a direction perpendicular to a major surface of the substrate is 5 to 15 angstroms (Å).

7. The display device of claim 2, wherein the side surface of the light emitting layer and the side surface of the cathode electrode are aligned in a same line.

8. The display device of claim 2, wherein the protective electrode includes an oxidation protective electrode positioned on the cathode electrode, and
the oxidation protective electrode includes Ag-alloy metal.

9. The display device of claim 8, wherein the oxidation protective electrode includes a side surface facing the non-light emission area, and
a third inclination angle of the side surface of the oxidation protective electrode with respect to an upper surface of the cathode electrode is 60° to 90°.

10. The display device of claim 9, wherein the oxidation protective electrode doesn't cover the side surface of the cathode electrode, which faces the non-light emission area.

11. The display device of claim 10, wherein a thickness of the oxidation protective electrode in a direction perpendicular to a major surface of the substrate is 80 to 150 Å.

12. The display device of claim 9, wherein the protective electrode further includes a moisture-permeable protective electrode positioned on the oxidation protective electrode, and
the moisture-permeable protective electrode includes a transparent oxide electrode.

13. The display device of claim 12, wherein the moisture-permeable protective electrode includes a side surface facing the non-light emission area, and
a fourth inclination angle of the side surface of the moisture-permeable protective electrode with respect to an upper surface of the oxidation protective electrode is 60° to 90°.

14. The display device of claim 13, wherein the moisture-permeable protective electrode doesn't cover the side surface of the oxidation protective electrode, which faces the non-light emission area.

15. The display device of claim 13, wherein a thickness of the moisture-permeable protective electrode in a direction perpendicular to a major surface of the substrate is 70 to 300 Å.

16. The display device of claim 13, wherein the pixel defining layer is in contact with the side surface of the moisture-permeable protective electrode, the side surface of the oxidation protective electrode, the side surface of the cathode electrode and the side surface of the light emitting layer, and
the pixel defining layer completely covers the side surface of the moisture-permeable protective electrode, the side surface of the oxidation protective electrode, the side surface of the cathode electrode and the side surface of the light emitting layer.

17. A display device comprising:
a substrate including a light emission area and a non-light emission area;
a first anode electrode positioned on the light emission area of the substrate;
a first cathode electrode positioned on the first anode electrode;
a first protective electrode positioned on the first cathode electrode;
a pixel defining layer positioned on the non-light emission area of the substrate;
a second anode electrode spaced apart from the first anode electrode with the pixel defining layer interposed therebetween;
a second cathode electrode positioned on the second anode electrode;
a second protective electrode positioned on the second cathode electrode; and
a common electrode positioned on the pixel defining layer and overlapped with the light emission area and the non-light emission area,
wherein the common electrode includes a first portion that is in contact with the first protective electrode, a second portion that is in contact with the second protective electrode and a third portion that is in contact with the pixel defining layer,
the third portion is positioned between the first portion and the second portion, and
the first portion and the second portion are extended from the third portion.

18. The display device of claim 17, wherein the first cathode electrode and the second cathode electrode are spaced apart from each other with the pixel defining layer interposed therebetween, and
the first cathode electrode and the second cathode electrode are electrically connected to each other by the common electrode.

19. The display device of claim 18, wherein the first protective electrode includes a first oxidation protective electrode positioned on the first cathode electrode and a first moisture-permeable protective electrode positioned on the first oxidation protective electrode,
the second protective electrode includes a second oxidation protective electrode positioned on the second cathode electrode and a second moisture-permeable protective electrode positioned on the second oxidation protective electrode,
the first moisture-permeable protective electrode and the second moisture-permeable protective electrode are spaced apart from each other, and
the first moisture-permeable protective electrode and the second moisture-permeable protective electrode are electrically connected to each other by the common electrode.

20. A method of fabricating a display device, the method comprising:
forming an anode electrode on a substrate, and sequentially stacking and forming a light emitting layer, a cathode electrode and a protective electrode on the anode electrode;
forming a photoresist on the protective electrode and then performing an etching process to simultaneously remove a portion of each of the light emitting layer, the cathode electrode and the protective electrode; and
forming a pixel defining layer covering an edge of the protective electrode and then forming a common electrode on the pixel defining layer, the common electrode being in contact with the protective electrode and electrically connected to the protective electrode,
wherein an inclination angle of a side surface of the light emitting layer with respect to an upper surface of the anode electrode is 60° to 90°.

21. An electronic device comprising:
a display device comprising:
a substrate including a light emission area and a non-light emission area;
an anode electrode positioned on the light emission area of the substrate;
a light emitting layer positioned on the anode electrode;
a cathode electrode positioned on the light emitting layer;
a protective electrode positioned on the cathode electrode;
a pixel defining layer positioned on the non-light emission area of the substrate, and defining an opening therein; and
a common electrode positioned on the pixel defining layer and in contact with the protective electrode at a portion that overlaps the opening,
wherein a first inclination angle of a side surface of the light emitting layer, which faces the non-light emission area, with respect to an upper surface of the anode electrode is 60° to 90°.
